(19) United States
(12) Patent Application Publication
(10) Pub. No.: US 2015/0193157 A1
(43) Pub. Date: Jul. 9, 2015

(54) METHOD OF READING PAGE DATA OF A NAND FLASH MEMORY DEVICE

(71) Applicant: The-AIO Inc., 8, Seongnam-si Gyeonggi-do (KR)

(72) Inventor: Sun-Mo Hwang, Suwon-si (KR)

(21) Appl. No.: 14/401,718

(22) PCT Filed: Apr. 18, 2013
(86) PCT No.: PCT/KR2013/003308

§ 371 Date: Mar. 24, 2015

(30) Foreign Application Priority Data
May 30, 2012 (KR) 10-2012-0057063

(51) Int. Cl. G06F 3/06; G11C 29/52; G06F 11/10

(52) U.S. Cl. CPC G06F 3/0619; G06F 3/0688; G06F 3/0656; G06F 11/1072; G11C 29/52

(57) ABSTRACT

A method of reading page data of a NAND flash memory device is provided. By the method, a plurality of page data that are read from a memory cell array of the NAND flash memory device are stored in a plurality of page buffers, respectively, buffer output data is generated by selecting respective portions of the page data in a vertical direction with respect to the page buffers, and then the buffer output data is output to a memory controller. Thus, the method may enable a memory system including the NAND flash memory device to operate at a high speed while achieving high reliability for the page data.

### CROSS-REFERENCE TO RELATED APPLICATION(S)

This application claims priority under 35 USC §119 to Korean Patent Application No. 10-2012-0057063, filed on May 30, 2012 in the Korean Intellectual Property Office (KIPO), the contents of which are incorporated herein in its entirety by reference.

### BACKGROUND

1. Technical Field

Example embodiments relate generally to a NAND flash memory device. More particularly, embodiments of the present inventive concept relate to a method of reading page data of a NAND flash memory device.

2. Description of the Related Art

Generally, a semiconductor memory device may be classified into two types (i.e., a volatile memory device and a non-volatile memory device) according to whether data can be retained when power is not supplied. Recently, a NAND flash memory device is widely used as the non-volatile memory device. In addition, the NAND flash memory device includes a plurality of multi-level cells (MLC) each storing data having a plurality of bits to be a mass storage device having a high degree of integration.

Generally, the NAND flash memory device performs a write operation and a read operation in a page unit, and performs an erase operation in a block unit. Thus, compared to a random access memory device (e.g., a dynamic random access memory (DRAM) device, etc), the NAND flash memory device has some restrictions to perform the write operation, the read operation, and the erase operation. In addition, as the number of bits programmed in respective multi-level cells included in the NAND flash memory device increases, a read failure rate of the NAND flash memory device may increase. As a result, reliability of the NAND flash memory device may be deteriorated.

To overcome these problems, in a conventional NAND flash memory device, a memory controller performs an error correction for page data when the page data is output to the memory controller via a page buffer. However, since a plurality of page data each stored in each page buffer are sequentially output to the memory controller in the conventional NAND flash memory device, the conventional NAND flash memory device cannot operate at a high speed due to a high read latency time when the error correction is performed by performing a hard decision and a soft decision.

### SUMMARY

Some example embodiments provide a method of reading page data of a NAND flash memory device capable of generating a portion group (i.e., referred to as buffer output data) by selecting a portion of every page data by a unit of one bit or by a unit of plural bits in a vertical direction with respect to a plurality of page buffers, and sequentially outputting the portion group to the memory controller when outputting a plurality of page data read from a memory cell array and stored in the page buffers to the memory controller.

Some example embodiments provide a method of reading page data of a NAND flash memory device capable of generating a portion group (i.e., referred to as buffer output data) by selecting a portion of every temporary page data by a unit of one bit or by a unit of plural bits in a vertical direction with respect to a plurality of page buffers, and sequentially outputting the portion group to the memory controller when outputting a plurality of temporary page data read from a memory cell array and stored in the page buffers to the memory controller. Here, in order to perform a soft decision and a hard decision, the temporary page data are generated by reading one page data based on a plurality of verification voltages.

According to an aspect of example embodiments, a method of reading page data of a NAND flash memory device may include an operation of storing a plurality of page data in a plurality of page buffers, respectively, the page data being read from a memory cell array of the NAND flash memory device, an operation of generating buffer output data by selecting respective portions of the page data in a vertical direction with respect to the page buffers, and an operation of outputting the buffer output data to a memory controller.

In example embodiments, the buffer output data may be bit-wise output data that is generated by selecting the respective portions of the page data by a unit of one bit in the vertical direction with respect to the page buffers.

In example embodiments, the buffer output data may be chunk-wise output data that is generated by selecting the respective portions of the page data by a unit of plural bits in the vertical direction with respect to the page buffers.

In example embodiments, the buffer output data may be stored in at least one buffer memory of the memory controller by categorizing the buffer output data by the page data.

In example embodiments, a size of the buffer output data may correspond to an input/output (I/O) size between the NAND flash memory device and the memory controller.

According to another aspect of example embodiments, a method of reading page data of a NAND flash memory device may include an operation of storing first through (N)th temporary page data, where N is an integer greater than or equal to 2, in first through (N)th page buffers, respectively, the first through (N)th temporary page data being generated by reading one page data from a memory cell array of the NAND flash memory device based on first through (N)th verification voltages, an operation of generating buffer output data by selecting respective portions of the first through (N)th temporary page data in a vertical direction with respect to the first through (N)th page buffers, and an operation of outputting the buffer output data to a memory controller.

In example embodiments, the buffer output data may be bit-wise output data that is generated by selecting the respective portions of the first through (N)th temporary page data by a unit of one bit in the vertical direction with respect to the first through (N)th page buffers.

In example embodiments, the buffer output data may be chunk-wise output data that is generated by selecting the respective portions of the first through (N)th temporary page data by a unit of plural bits in the vertical direction with respect to the first through (N)th page buffers.

In example embodiments, the buffer output data may be stored in at least one buffer memory of the memory controller by categorizing the buffer output data by the first through (N)th temporary page data. In addition, an error correction for the page data may be performed based on the buffer output data provided to the buffer memory of the memory controller.

In example embodiments, a size of the buffer output data may correspond to an input/output (I/O) size between the NAND flash memory device and the memory controller.

Therefore, a method of reading page data of a NAND flash memory device according to example embodiments may generate buffer output data (i.e., bit-wise output data or chunk-wise output data) by selecting a portion of every page data by a unit of one bit or by a unit of plural bits in a vertical direction with respect to a plurality of page buffers, and may sequentially output the buffer output data to the memory controller when outputting a plurality of page data read from a memory cell array and stored in the page buffers to the memory controller. As a result, a memory system including the NAND flash memory device may efficiently perform a read operation for the page data.

In addition, a method of reading page data of a NAND flash memory device according to example embodiments may generate buffer output data (i.e., bit-wise output data or chunk-wise output data) by selecting a portion of every temporary page data by a unit of one bit or by a unit of plural bits in a vertical direction with respect to a plurality of page buffers, and may sequentially output the buffer output data to the memory controller when outputting a plurality of temporary page data read from a memory cell array and stored in the page buffers to the memory controller. Here, in order to perform a soft decision and a hard decision, the temporary page data are generated by reading one page data based on a plurality of verification voltages. As a result, a memory system including the NAND flash memory device may operate at a high speed while achieving high reliability for the page data.

### BRIEF DESCRIPTION OF THE DRAWINGS

Illustrative, non-limiting example embodiments will be more clearly understood from the following detailed description taken in conjunction with the accompanying drawings.

FIG. 1 is a flowchart illustrating a method of reading page data of a NAND flash memory device according to example embodiments.

FIG. 2A is a diagram for describing a conventional method of reading page data of a NAND flash memory device.

FIG. 2B is a diagram for describing the method of FIG. 1.

FIG. 3 is a diagram illustrating an example embodiment in which bit-wise output data are output by the method of FIG. 1.

FIG. 4 is a diagram illustrating an example embodiment in which chunk-wise output data are output by the method of FIG. 1.

FIG. 5 is a flowchart illustrating a method of reading page data of a NAND flash memory device according to example embodiments.

FIG. 6 is a diagram illustrating an example embodiment in which temporary page data are generated by the method of FIG. 5.

FIG. 7 is a diagram illustrating an example embodiment in which bit-wise output data are output by the method of FIG. 5.

FIG. 8 is a diagram illustrating an example embodiment in which chunk-wise output data are output by the method of FIG. 5.

FIG. 9 is a block diagram illustrating a NAND flash memory device employing a method of reading page data according to example embodiments.

FIG. 10 is a block diagram illustrating a memory system including the NAND flash memory device of FIG. 9.

### DETAILED DESCRIPTION OF THE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

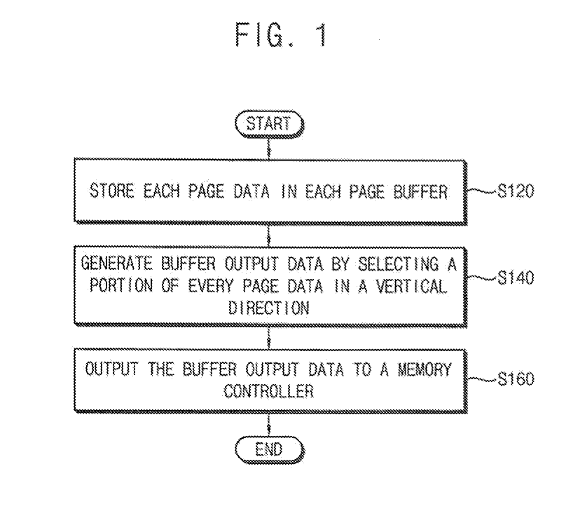

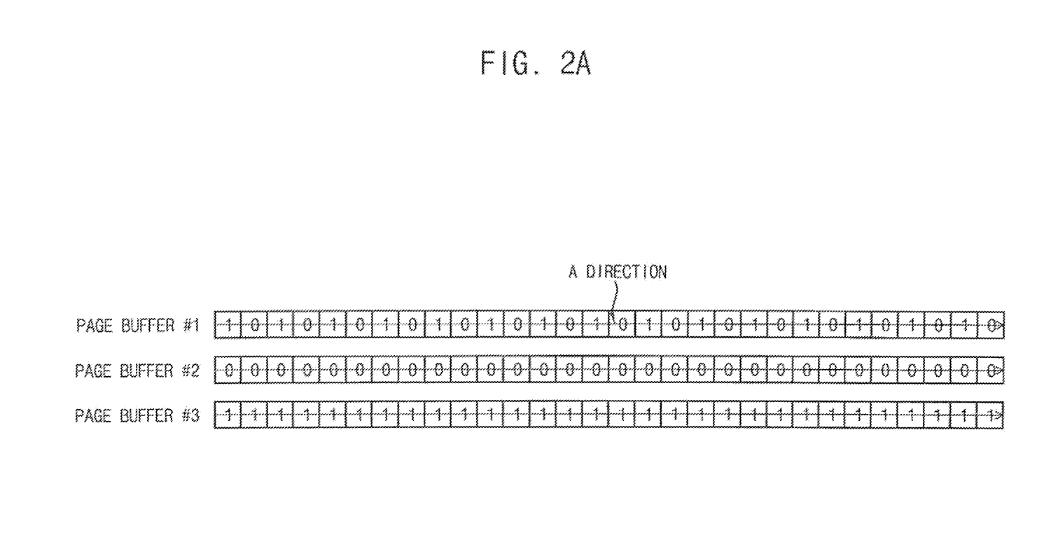

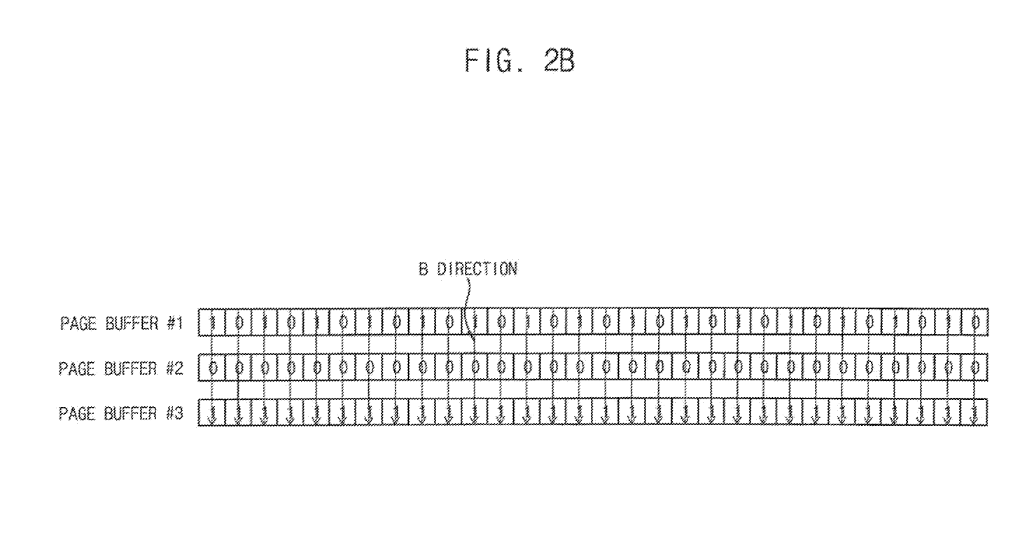

FIG. 1 is a flowchart illustrating a method of reading page data of a NAND flash memory device according to example embodiments. FIG. 2A is a diagram for describing a conventional method of reading page data of a NAND flash memory device. FIG. 2B is a diagram for describing the method of FIG. 1.

Referring to FIGS. 1 through 2B, the method of FIG. 1 may read a plurality of page data from a memory cell array to store each page data in each page buffer PAGE BUFFER #1, PAGE BUFFER #2, and PAGE BUFFER #3 (Step S120). Subsequently, the method of FIG. 1 may generate buffer output data by selecting a portion of every page data (i.e., by selecting respective portions of the page data) in a vertical direction (i.e., indicated as B DIRECTION) with respect to the page buffers PAGE BUFFER #1, PAGE BUFFER #2, and PAGE BUFFER #3 (Step S140). Next, the method of FIG. 1 may output the buffer output data to a memory controller (Step S160).

FIG. 2A shows the conventional method of reading the page data. As illustrated in FIG. 2A, the conventional method of reading the page data sequentially outputs a plurality of page data stored in the page buffers PAGE BUFFER #1, PAGE BUFFER #2, and PAGE BUFFER #3 to a memory controller, where each page data is stored in each of the page buffers PAGE BUFFER #1, PAGE BUFFER #2, and PAGE BUFFER #3 as the page data are read from a memory cell array. For example, after first page data stored in the first page buffer PAGE BUFFER #1 is output to the memory controller, second page data stored in the second page buffer PAGE BUFFER #2 is output to the memory controller. In addition, after the second page data stored in the second page buffer PAGE BUFFER #2 is output to the memory controller, third page data stored in the third page buffer PAGE BUFFER #3 is output to the memory controller. Here, an output sequence of the first through third page data may be changed according to requirements of the NAND flash memory device. As described above, in the conventional method of reading the page data, the page data stored in one page buffer (e.g., PAGE BUFFER #1, PAGE BUFFER #2, and PAGE BUFFER #3) is output to the memory controller after the page data stored in another page buffer (e.g., PAGE BUFFER #1, PAGE BUFFER #2, and PAGE BUFFER #3) is all output to the memory controller. Therefore, when an input/output (I/O) size between the memory controller and the NAND flash memory device is eight bits, the page data stored in a page buffer (e.g., PAGE BUFFER #1, PAGE BUFFER #2, and PAGE BUFFER #3) is output to the memory controller by a unit of eight bits in an arrow direction (i.e., indicated as A DIRECTION). After the page data stored in the page buffer (e.g., PAGE BUFFER #1, PAGE BUFFER #2, and PAGE BUFFER #3) is all output to the memory controller, the page data stored in a next page buffer (e.g., PAGE BUFFER #1, PAGE BUFFER #2, and PAGE BUFFER #3) is output to the memory controller by a unit of eight bits in the arrow direction (i.e., indicated as A DIRECTION). In this way, the page data stored in the page buffers PAGE BUFFER #1, PAGE BUFFER #2, and PAGE BUFFER #3 are sequentially output to the memory controller. In this specification, the arrow direction illustrated in FIG. 2A (i.e., indicated as A DIRECTION) is defined as a horizontal direction with respect to the page buffers PAGE BUFFER #1, PAGE BUFFER #2, and PAGE BUFFER #3.

As described above, in the conventional method of reading the page data, the page data stored in one page buffer (e.g., PAGE BUFFER #1, PAGE BUFFER #2, and PAGE BUFFER #3) is output to the memory controller after the page data stored in another page buffer (e.g., PAGE BUFFER #1, PAGE BUFFER #2, and PAGE BUFFER #3) is all output to the memory controller. As a result, it is difficult for a memory system including the NAND flash memory device to efficiently perform a read operation for the page data. In addition, when the page data stored in the page buffers PAGE BUFFER #1, PAGE BUFFER #2, and PAGE BUFFER #3 correspond to temporary page data for performing a soft decision and a hard decision, where the temporary page data are generated by reading one page data based on a plurality of verification voltages, an error correction can be performed in the memory controller only after the temporary page data are all output to the memory controller. That is, in the conventional method of reading the page data, since the error correction cannot be performed while the temporary page data are output to the memory controller, the memory system including the NAND flash memory device cannot operate at a high speed due to a high read latency time. On the other hand, as illustrated in FIG. 2B, the method of FIG. 1 may output the page data stored in the page buffers PAGE BUFFER #1, PAGE BUFFER #2, and PAGE BUFFER #3 to the memory controller in a vertical direction with respect to the page buffers PAGE BUFFER #1, PAGE BUFFER #2, and PAGE BUFFER #3 (i.e., indicated as B DIRECTION). Thus, the method of FIG. 1 may enable the memory system including the NAND flash memory device to efficiently perform a read operation for the page data. In this specification, an arrow direction illustrated in FIG. 2B (i.e., indicated as B DIRECTION) is defined as a vertical direction with respect to the page buffers PAGE BUFFER #1, PAGE BUFFER #2, and PAGE BUFFER #3. Hereinafter, the method of FIG. 1 will be described with reference to FIG. 2B.

Specifically, the method of FIG. 1 may read the page data from the memory cell array to store each page data in each page buffer PAGE BUFFER #1, PAGE BUFFER #2, and PAGE BUFFER #3 (Step S120). For convenience of description, the page data stored in the first page buffer PAGE BUFFER #1 may be referred to as first page data, the page data stored in the second page buffer PAGE BUFFER #2 may be referred to as second page data, and the page data stored in the third page buffer PAGE BUFFER #3 may be referred to as third page data. Subsequently, the method of FIG. 1 may generate the buffer output data by selecting a portion of every page data in the vertical direction (i.e., indicated as B DIRECTION) with respect to the page buffers PAGE BUFFER #1, PAGE BUFFER #2, and PAGE BUFFER #3 (Step S140). Here, a size of the buffer output data corresponds to the I/O size between the NAND flash memory device and the memory controller. In an example embodiment, the buffer output data may be the bit-wise output data generated by selecting a portion of the first page data, a portion of the second page data, and a portion of the third page data by a unit of one bit. That is, the bit-wise output data may be generated by selecting a portion of every page data by a unit of one bit. For example, when the I/O size between the memory controller and the NAND flash memory device is eight bits, the first buffer output data may be generated by sequentially selecting a first bit of the first page data, a first bit of the second page data, a first bit of the third page data, a second bit of the first page data, a second bit of the second page data, a second bit of the third page data, a third bit of the first page data, and a third bit of the second page data. In addition, the second buffer output data may be generated by sequentially selecting a third bit of the third page data, a fourth bit of the first page data, a fourth bit of the second page data, a fourth bit of the third page data, a fifth bit of the first page data, a fifth bit of the second page data, a fifth bit of the third page data, and a sixth bit of the first page data. In this way, the buffer output data may be sequentially generated. However, the present inventive concept is not limited thereto.

In another example embodiment, the buffer output data may be the chunk-wise output data generated by selecting a portion of the first page data, a portion of the second page data, and a portion of the third page data by a unit of plural bits (i.e., chunk). That is, the chunk-wise output data may be generated by selecting a portion of every page data by a unit of plural bits. For example, when the I/O size between the memory controller and the NAND flash memory device is eight bits and a size of chunk is two bits, the first buffer output data may be generated by sequentially selecting first and second bits of the first page data, first and second bits of the second page data, first and second bits of the third page data, and third and fourth bits of the first page data. In addition, the second buffer output data may be generated by sequentially selecting third and fourth bits of the second page data, third and fourth bits of the third page data, fifth and sixth bits of the first page data, and fifth and sixth bits of the second page data. In this way, the buffer output data may be sequentially generated. However, the present inventive concept is not limited thereto. As described above, the buffer output data may be generated by selecting a portion of the first page data, a portion of the second page data, and a portion of the third page data by a unit of one bit or by a unit of plural bits in the vertical direction with respect to the first through third page buffers PAGE BUFFER #1, PAGE BUFFER #2, and PAGE BUFFER #3 (i.e., indicated as B DIRECTION). Here, since a size of the buffer output data corresponds to the I/O size between the NAND flash memory device and the memory controller, the buffer output data may be sequentially output to the memory controller. Although it is illustrated in FIG. 2B that the first through third page buffers PAGE BUFFER #1, PAGE BUFFER #2, and PAGE BUFFER #3 are arranged in the vertical direction (i.e., indicated as B DIRECTION) with respect to the first through third page buffers PAGE BUFFER #1, PAGE BUFFER #2, and PAGE BUFFER #3, an actual arrangement of the first through third page buffers PAGE BUFFER #1, PAGE BUFFER #2, and PAGE BUFFER #3 in the NAND flash memory device is not limited thereto. In other words, the vertical direction (i.e., indicated as B DIRECTION) with respect to the first through third page buffers PAGE BUFFER #1, PAGE BUFFER #2, and PAGE BUFFER #3 should be interpreted as a way of sequentially selecting a portion of the first page data stored in the first page buffer PAGE BUFFER #1, a portion of the second page data stored in the second page buffer PAGE BUFFER #2, and a portion of the third page data stored in the third page buffer PAGE BUFFER #3 by a unit of one bit or by a unit of plural bits.

Next, the method of FIG. 1 may output the buffer output data to the memory controller (Step S160). Here, the buffer output data may be stored in at least one buffer memory of the memory controller. Specifically, the buffer output data may be stored in at least one buffer memory of the memory controller by categorizing (or, dividing) the buffer output data by page data. For example, the buffer memory may be a static random access memory (SRAM) device. However, the buffer memory is not limited thereto. In addition, the buffer memory may have a size that is M times that of the page data, where M is an integer greater than or equal to 1. Further, the number of the buffer memory may be determined according to requirements of the memory system. Thus, each page data may be stored in each buffer memory included in the memory controller (e.g., when the memory controller includes a plurality of buffer memories), or may be stored in each region of one buffer memory included in the memory controller (e.g., when the memory controller includes one buffer memory having a plurality of regions). For convenience of description, it is assumed below that each page data is stored in each buffer memory of the memory controller. As described above, the buffer output data provided to the memory controller may include a portion of the first page data, a portion of the second page data, and a portion of the third page data. Therefore, when the buffer output data are stored in a plurality of buffer memories of the memory controller, a portion of the first page data may be stored in a first buffer memory, a portion of the second page data may be stored in a second buffer memory, and a portion of the third page data may be stored in a third buffer memory. In this way, the first through third page data of the first through third page buffers PAGE BUFFER #1, PAGE BUFFER #2, and PAGE BUFFER #3 may be stored in the first through third buffer memories of the memory controller, respectively. In other words, the first page data may be stored in the first buffer memory of the memory controller, the second page data may be stored in the second buffer memory of the memory controller, and the third page data may be stored in the third buffer memory of the memory controller. In brief, the method of FIG. 1 may generate the buffer output data (i.e., the bit-wise output data or the chunk-wise output data) by selecting a portion of every page data by a unit of one bit or by a unit of plural bits in the vertical direction with respect to the page buffers PAGE BUFFER #1, PAGE BUFFER #2, and PAGE BUFFER #3 (i.e., indicated as B DIRECTION), and may sequentially output the buffer output data to the memory controller when outputting a plurality of page data read from the memory cell array and stored in the page buffers PAGE BUFFER #1, PAGE BUFFER #2, and PAGE BUFFER #3 to the memory controller. As a result, the method of FIG. 1 may enable the memory system including the NAND flash memory device to efficiently perform a read operation for the page data.

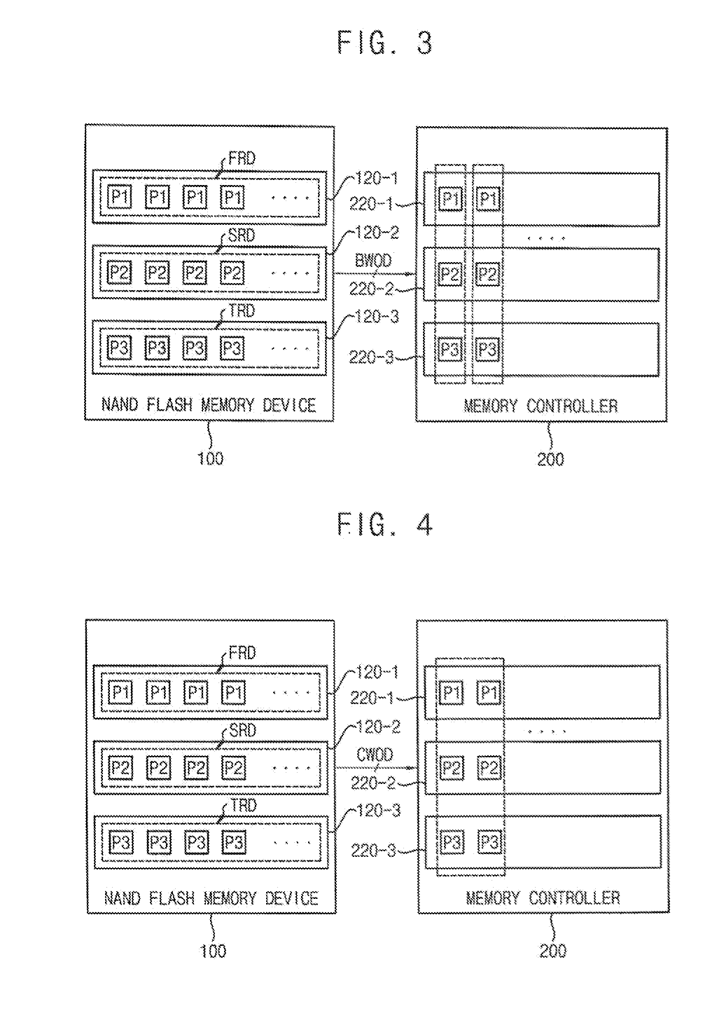

FIG. 3 is a diagram illustrating an example embodiment in which bit-wise output data are output by the method of FIG. 1.

Referring to FIG. 3, the NAND flash memory device 100 may include first through third page buffers 120-1, 120-2, and 120-3, and the memory controller 200 may include first through third buffer memories 220-1, 220-2, and 220-3. Here, the bit-wise output data BWOD may be output from the NAND flash memory device 100 to the memory controller 200 by the method of FIG. 1. Although it is illustrated in FIG. 3 that the first through third page buffers 120-1, 120-2, and 120-3 are arranged in a vertical direction with respect to the first through third page buffers 120-1, 120-2, and 120-3, and the first through third buffer memories 220-1, 220-2, and 220-3 are also arranged in a vertical direction with respect to the first through third buffer memories 220-1, 220-2, and 220-3, an actual arrangement of the first through third page buffers 120-1, 120-2, and 120-3 and an actual arrangement of the first through third buffer memories 220-1, 220-2, and 220-3 are not limited thereto. For convenience of description, it is assumed in FIG. 3 that an I/O size between the NAND flash memory device 100 and the memory controller 200 is three bits.

Specifically, when the first through third page data FRD, SRD, and TRD are read from a memory cell array and respectively stored in the first through third page buffers 120-1, 120-2, and 120-3, the bit-wise output data BWOD (i.e., the buffer output data) may be generated by selecting respective portions of the first through third page data FRD, SRD, and TRD by a unit of one bit in a vertical direction with respect to the first through third page buffers 120-1, 120-2, and 120-3. For example, the bit-wise output data BWOD may be generated by selecting one bit P1 of the first page data FRD, one bit P2 of the second page data SRD, and one bit P3 of the third page data TRD. In this case, the bit-wise output data BWOD may have three bits corresponding to the I/O size between the NAND flash memory device 100 and the memory controller 200. Thus, the bit-wise output data BWOD may include a portion of the first page data FRD, a portion of the second page data SRD, and a portion of the third page data TRD. Subsequently, the bit-wise output data BWOD may be output to the memory controller 200, and then may be stored in the first through third buffer memories 220-1, 220-2, and 220-3 of the memory controller 200 by categorizing the bit-wise output data BWOD by the first through third page data FRD, SRD, and TRD. That is, when the bit-wise output data BWOD are stored in the first through third buffer memories 220-1, 220-2, and 220-3 of the memory controller 200, one bit P1 of the first page data FRD may be stored in the first buffer memory 220-1, one bit P2 of the second page data SRD may be stored in the second buffer memory 220-2, and one bit P3 of the third page data TRD may be stored in the third buffer memory 220-3. In this way, the first through third page data FRD, SRD, and TRD stored in the first through third page buffers 120-1, 120-2, and 120-3 of the NAND flash memory device 100 may be stored in the first through third buffer memories 220-1, 220-2, and 220-3 of the memory controller 200, respectively. Next, the first through third page data FRD, SRD, and TRD stored in the first through third buffer memories 220-1, 220-2, and 220-3 may be output to a host device. As a result, the method of FIG. 1 may enable a memory system including the NAND flash memory device 100 to efficiently perform a read operation for the first through third page data FRD, SRD, and TRD.

FIG. 4 is a diagram illustrating an example embodiment in which chunk-wise output data are output by the method of FIG. 1.

Referring to FIG. 4, the NAND flash memory device 100 may include first through third page buffers 120-1, 120-2, and 120-3, and the memory controller 200 may include first through third buffer memories 220-1, 220-2, and 220-3. Here, the chunk-wise output data CWOD may be output from the NAND flash memory device 100 to the memory controller 200 by the method of FIG. 1. Although it is illustrated in FIG. 4 that the first through third page buffers 120-1, 120-2, and 120-3 are arranged in a vertical direction with respect to the first through third page buffers 120-1, 120-2, and 120-3, and the first through third buffer memories 220-1, 220-2, and 220-3 are also arranged in a vertical direction with respect to the first through third buffer memories 220-1, 220-2, and 220-3, an actual arrangement of the first through third page buffers 120-1, 120-2, and 120-3 and an actual arrangement of the first through third buffer memories 220-1, 220-2, and 220-3 are not limited thereto. For convenience of description, it is assumed in FIG. 4 that an I/O size between the NAND flash memory device 100 and the memory controller 200 is six bits.

Specifically, when the first through third page data FRD, SRD, and TRD are read from a memory cell array and respectively stored in the first through third page buffers 120-1, 120-2, and 120-3, the chunk-wise output data CWOD (i.e., the buffer output data) may be generated by selecting respective portions of the first through third page data FRD, SRD, and TRD by a unit of plural bits (i.e., chunk) in a vertical direction with respect to the first through third page buffers 120-1, 120-2, and 120-3. Here, a size of chunk may be determined according to requirements of a memory system. For example, the chunk-wise output data CWOD may be generated by selecting plural bits P1 and P1 of the first page data FRD, plural bits P2 and P2 of the second page data SRD, and plural bits P3 and P3 of the third page data TRD. In this case, the chunk-wise output data CWOD may have six bits corresponding to the I/O size between the NAND flash memory device 100 and the memory controller 200. Thus, the chunk-wise output data CWOD may include a portion of the first page data FRD, a portion of the second page data SRD, and a portion of the third page data TRD. Subsequently, the chunk-wise output data CWOD may be output to the memory controller 200, and then may be stored in the first through third buffer memories 220-1, 220-2, and 220-3 of the memory controller 200 by categorizing the chunk-wise output data CWOD by the first through third page data FRD, SRD, and TRD. That is, when the chunk-wise output data CWOD are stored in the first through third buffer memories 220-1, 220-2, and 220-3 of the memory controller 200, plural bits P1 and P1 of the first page data FRD may be stored in the first buffer memory 220-1, plural bits P2 and P2 of the second page data SRD may be stored in the second buffer memory 220-2, and plural bits P3 and P3 of the third page data TRD may be stored in the third buffer memory 220-3. In this way, the first through third page data FRD, SRD, and TRD stored in the first through third page buffers 120-1, 120-2, and 120-3 of the NAND flash memory device 100 may be stored in the first through third buffer memories 220-1, 220-2, and 220-3 of the memory controller 200, respectively. Next, the first through third page data FRD, SRD, and TRD stored in the first through third buffer memories 220-1, 220-2, and 220-3 may be output to a host device. As a result, the method of FIG. 1 may enable a memory system including the NAND flash memory device 100 to efficiently perform a read operation for the first through third page data FRD, SRD, and TRD.

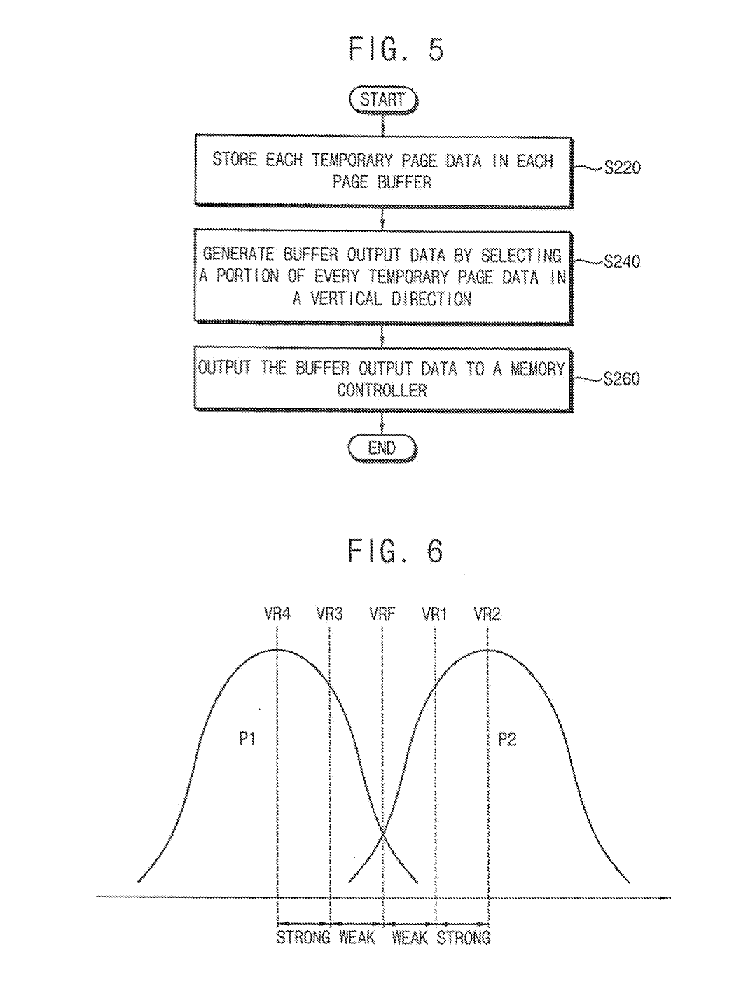

FIG. 5 is a flowchart illustrating a method of reading page data of a NAND flash memory device according to example embodiments.

Referring to FIG. 5, the method of FIG. 5 may read one page data from a memory cell array based on first through (N)th verification voltages, where N is an integer greater than or equal to 2, to store first through (N)th temporary page data in first through (N)th page buffers, respectively (Step S220). Subsequently, the method of FIG. 5 may generate buffer output data by selecting a portion of every temporary page data (i.e., by selecting respective portions of the first through (N)th temporary page data) in a vertical direction with respect to the first through (N)th page buffers (Step S240). Next, the method of FIG. 5 may output the buffer output data to a memory controller (Step S260). Here, to perform a hard decision and a soft decision, the first through (N)th temporary page data stored in the first through (N)th page buffers may be generated by reading one page data from the memory cell array based on a plurality of verification voltages (i.e., the first through (N)th verification voltages). Thus, an error correction may be performed by performing the hard decision and the soft decision based on the first through (N)th temporary page data. As described above, the method of FIG. 5 may output the first through (N)th temporary page data stored in the first through (N)th page buffers to the memory controller in a vertical direction with respect to the first through (N)th page buffers. For convenience of description, the temporary page data stored in the (K)th page buffer will be referred to as the (K)th temporary page data, where K is an integer between 1 and N.

Specifically, the method of FIG. 5 may read one page data from the memory cell array based on the first through (N)th verification voltages to store the first through (N)th temporary page data in the first through (N)th page buffers, respectively (Step S220). A memory system including the NAND flash memory device may perform the error correction by performing a hard decision and a soft decision. Thus, the first through (N)th verification voltages may include a reference verification voltage and a plurality of additional verification voltages, where the additional verification voltages are generated by changing (i.e., increasing or decreasing) the reference verification voltage by a predetermined voltage. For example, the first temporary page data may be generated by reading one page data based on the first verification voltage (e.g., the reference verification voltage), the second temporary page data may be generated by reading the page data based on the second verification voltage (e.g., the first additional verification voltage), and the third temporary page data may be generated by reading the page data based on the third verification voltage (e.g., the second additional verification voltage). Here, the temporary page data generated by reading one page data based on the reference verification voltage may correspond to hard decision data, and the temporary page data generated by reading the page data based on the additional verification voltages may correspond to soft decision data. Thus, the memory controller may perform the error correction for the page data based on the hard decision data and its error correction code (i.e., performing a hard decision). In addition, the memory controller may perform a further error correction for the page data based on additional information (i.e., soft decision data) related to reliability of the hard decision data (i.e., performing a soft decision). Generally, the soft decision data may include more information compared to the hard decision data. Hence, a further error correction can be performed when the memory controller further uses the soft decision data (i.e., information theory). Therefore, when the memory controller performs both the hard decision and the soft decision, the memory system including the NAND flash memory device may achieve high reliability for the page data. To this end, the method of FIG. 5 may generate the first through (N)th temporary page data by reading one page data from the memory cell array of the NAND flash memory device based on the first through (N)th verification voltages, and may output the first through (N)th temporary page data to the memory controller in order that the memory controller performs both the hard decision and the soft decision.

Subsequently, the method of FIG. 5 may generate the buffer output data by selecting a portion of every temporary page data (i.e., the first through (N)th temporary page data) in the vertical direction with respect to the first through (N)th page buffers (Step S240). Here, a size of the buffer output data corresponds to the I/O size between the NAND flash memory device and the memory controller. In an example embodiment, the buffer output data may be the bit-wise output data generated by selecting a portion of every temporary page data by a unit of one bit. For example, when the I/O size between the memory controller and the NAND flash memory device is eight bits and N is 3, the first buffer output data may be generated by sequentially selecting a first bit of the first temporary page data, a first bit of the second temporary page data, a first bit of the third temporary page data, a second bit of the first temporary page data, a second bit of the second temporary page data, a second bit of the third temporary page data, a third bit of the first temporary page data, and a third bit of the second temporary page data. In addition, the second buffer output data may be generated by sequentially selecting a third bit of the third temporary page data, a fourth bit of the first temporary page data, a fourth bit of the second temporary page data, a fourth bit of the third temporary page data, a fifth bit of the first temporary page data, a fifth bit of the second temporary page data, a fifth bit of the third temporary page data, and a sixth bit of the first temporary page data. In this way, the buffer output data may be sequentially generated. However, the present inventive concept is not limited thereto.

In another example embodiment, the buffer output data may be the chunk-wise output data generated by selecting a portion of every temporary page data (i.e., the first through (N)th temporary page data) by a unit of plural bits (i.e., chunk). For example, when the I/O size between the memory controller and the NAND flash memory device is eight bits, a size of chunk is two bits, and N is 3, the first buffer output data may be generated by sequentially selecting first and second bits of the first temporary page data, first and second bits of the second temporary page data, first and second bits of the third temporary page data, and third and fourth bits of the first temporary page data. In addition, the second buffer output data may be generated by sequentially selecting third and fourth bits of the second temporary page data, third and fourth bits of the third temporary page data, fifth and sixth bits of the first temporary page data, and fifth and sixth bits of the second temporary page data. In this way, the buffer output data may be sequentially generated. However, the present inventive concept is not limited thereto. As described above, the buffer output data may be generated by selecting a portion of every temporary page data (i.e., the first through (N)th temporary page data) by a unit of one bit or by a unit of plural bits in the vertical direction with respect to the first through (N)th page buffers. Here, since a size of the buffer output data corresponds to the I/O size between the NAND flash memory device and the memory controller, the buffer output data may be sequentially output to the memory controller. As mentioned above, the vertical direction with respect to the first through (N)th page buffers is not determined by an actual arrangement of the first through (N)th page buffers. That is, the vertical direction with respect to the first through (N)th page buffers should be interpreted as a way of sequentially selecting a portion of every temporary page data (i.e., the first through (N)th temporary page data) stored in the first through (N)th page buffers by a unit of one bit or by a unit of plural bits.

Next, the method of FIG. 5 may output the buffer output data to the memory controller (Step S260). Here, the buffer output data may be stored in at least one buffer memory of the memory controller. Specifically, the buffer output data may be stored in at least one buffer memory of the memory controller by categorizing (or, dividing) the buffer output data by temporary page data (i.e., the first through (N)th temporary page data). For example, the buffer memory may be an SRAM device. However, the buffer memory is not limited thereto. In addition, the buffer memory may have a size that is M times that of the temporary page data, where M is an integer greater than or equal to 1. Further, the number of the buffer memory may be determined according to requirements of the memory system. Thus, each of the first through (N)th temporary page data may be stored in each buffer memory included in the memory controller (e.g., when the memory controller includes a plurality of buffer memories), or may be stored in each region of one buffer memory included in the memory controller (e.g., when the memory controller includes one buffer memory having a plurality of regions). For convenience of description, it is assumed below that each of the first through (N)th temporary page data is stored in each buffer memory of the memory controller. As described above, the buffer output data provided to the memory controller may include a portion of the first temporary page data, a portion of the second temporary page data, and a portion of the third temporary page data. Therefore, when the buffer output data are stored in a plurality of buffer memories of the memory controller, a portion of the first temporary page data may be stored in a first buffer memory, a portion of the second temporary page data may be stored in a second buffer memory, and a portion of the third temporary page data may be stored in a third buffer memory. In this way, the first through third temporary page data of the first through (N)th page buffers may be stored in the first through (N)th buffer memories of the memory controller, respectively. In other words, the first temporary page data may be stored in the first buffer memory of the memory controller, the second temporary page data may be stored in the second buffer memory of the memory controller, and the third temporary page data may be stored in the third buffer memory of the memory controller.

As described above, the memory controller may perform the error correction for the page data based on the buffer output data. For this operation, the memory controller may use the first through (N)th temporary page data. In a conventional method of reading page data, the first through (N)th temporary page data stored in the first through (N)th page buffers are sequentially output to the memory controller. Thus, in the conventional method of reading the page data, the temporary page data stored in one page buffer is output to the memory controller after the temporary page data stored in another page buffer is output to the memory controller. Here, since an error correction is performed based on the first through (N)th temporary page data in the memory controller, the error correction can be performed only after the first through (N)th temporary page data are all output to the memory controller. As a result, the memory system including the NAND flash memory device cannot operate at a high speed due to a high read latency time. As described above, however, the method of FIG. 5 may generate the buffer output data by selecting a portion of every temporary page data (i.e., the first through (N)th temporary page data) by a unit of one bit or by a unit of plural bits in the vertical direction with respect to the first through (N)th page buffers, and may output (or, provide) the buffer output data to the memory controller. Thus, the method of FIG. 5 may enable the memory system including the NAND flash memory device to perform the error correction for the page data based on the first through (N)th temporary page data while outputting the first through (N)th temporary page data to the memory controller. Next, an error correction result based on the first through (N)th temporary page data (i.e., error-corrected page data) may be stored in the buffer memory of the memory controller, and then output to a host device. As a result, the method of FIG. 5 may enable the memory system including the NAND flash memory device to operate at a high speed while achieving high reliability for the page data.

FIG. 6 is a diagram illustrating an example embodiment in which temporary page data are generated by the method of FIG. 5.

Referring to FIG. 6, the method of FIG. 5 may perform an error correction by performing a hard decision and a soft decision. Generally, a multi-level cell capable of storing K bits may have K states, where K is an integer greater than or equal to 2. In addition, the K states may be verified by respective verification voltages. Here, a threshold voltage distribution is formed by threshold voltages of multi-level cells each capable of storing K bits. Since a voltage window is restricted, a distance among the K states may decrease as K increases. Thus, adjacent states among the K states may partially overlap with each other. As a result, an error may occur in the page data even when the K states are verified with respective verification voltages for each multi-level cell.

For convenience of description, only two states (i.e., S1 and S2) that are adjacent to each other are illustrated in FIG. 6. For example, as illustrated in FIG. 6, when the two states (i.e., S1 and S2) partially overlap with each other, the two states (i.e., S1 and S2) may be verified (or, distinguished) by a reference verification voltage VRF. That is, a multi-level cell having a threshold voltage higher than the reference verification voltage VRF may be verified (or, determined) to have a second state S2, and a multi-level cell having a threshold voltage lower than the reference verification voltage VRF may be verified to have a first state S1. However, in an overlapping region between the first state Si and the second state S2, a multi-level cell having the first state S1 may be verified to have the second state S2, and a multi-level cell having the second state S2 may be verified to have the first state S1. As a result, reliability of verification performed on the multi-level cells in the overlapping region between the first state S1 and the second state S2 may be relatively low (i.e., indicated as WEAK), and reliability of verification performed on the multi-level cells in a region other than the overlapping region between the first state Si and the second state S2 may be relatively high (i.e., indicated as STRONG). Therefore, when one temporary page data generated by reading one page data based on the reference verification voltage VRF (i.e., hard decision data) and a plurality of temporary page data generated by reading the page data based on the additional verification voltages VR1, VR2, VR3, and VR4 (i.e., soft decision data) are output to the memory controller, the memory controller may perform an error correction for the page data based on the hard decision data and its error correction code (i.e., performing a hard decision), and may perform a further error correction for the page data based on additional information (i.e., the soft decision data) related to reliability of the hard decision data (i.e., performing a soft decision). Here, the additional verification voltages VR1, VR2, VR3, and VR4 may be generated by changing (i.e., increasing or decreasing) the reference verification voltage VRF by a predetermined voltage. As described above, since the method of FIG. 5 generates buffer output data by selecting a portion of every temporary page data by a unit of one bit or by a unit of plural bits in a vertical direction with respect to page buffers and sequentially provides the buffer output data to the memory controller, the method of FIG. 5 may perform an error correction for page data based on temporary page data while outputting the temporary page data to the memory controller. As a result, the method of FIG. 5 may enable a memory system including the NAND flash memory device to operate at a high speed while achieving high reliability for the page data.

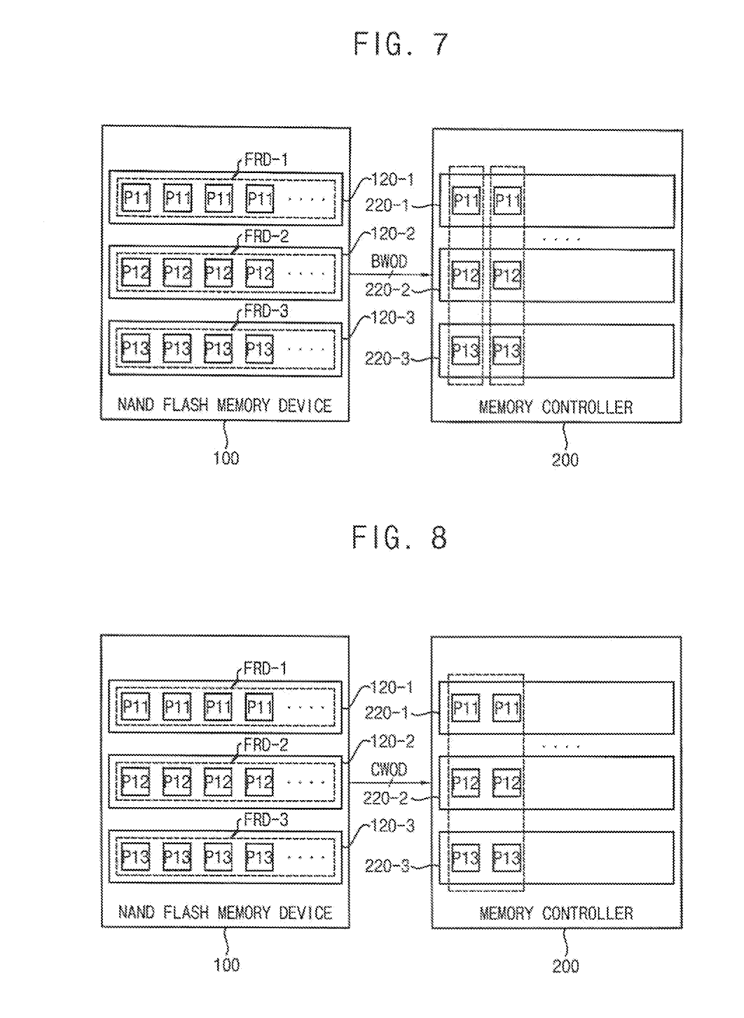

FIG. 7 is a diagram illustrating an example embodiment in which bit-wise output data are output by the method of FIG. 5.

Referring to FIG. 7, the NAND flash memory device 100 may include first through third page buffers 120-1, 120-2, and 120-3, and the memory controller 200 may include first through third buffer memories 220-1, 220-2, and 220-3. Here, the bit-wise output data BWOD may be output from the NAND flash memory device 100 to the memory controller 200 by the method of FIG. 5. Although it is illustrated in FIG. 7 that the first through third page buffers 120-1, 120-2, and 120-3 are arranged in a vertical direction with respect to the first through third page buffers 120-1, 120-2, and 120-3, and the first through third buffer memories 220-1, 220-2, and 220-3 are also arranged in a vertical direction with respect to the first through third buffer memories 220-1, 220-2, and 220-3, an actual arrangement of the first through third page buffers 120-1, 120-2, and 120-3 and an actual arrangement of the first through third buffer memories 220-1, 220-2, and 220-3 are not limited thereto. For convenience of description, it is assumed in FIG. 7 that an I/O size between the NAND flash memory device 100 and the memory controller 200 is three bits.

Specifically, when the first through third temporary page data FRD-1, FRD-2, and FRD-3 are generated by reading one page data based on first through third verification voltages from a memory cell array and respectively stored in the first through third page buffers 120-1, 120-2, and 120-3, the bit-wise output data BWOD (i.e., the buffer output data) may be generated by selecting respective portions of the first through third temporary page data FRD-1, FRD-2, and FRD-3 by a unit of one bit in a vertical direction with respect to the first through third page buffers 120-1, 120-2, and 120-3. For example, the bit-wise output data BWOD may be generated by selecting one bit P11 of the first temporary page data FRD-1, one bit P12 of the second temporary page data FRD-2, and one bit P13 of the third temporary page data FRD-3. In this case, the bit-wise output data BWOD may have three bits corresponding to the I/O size between the NAND flash memory device 100 and the memory controller 200. Thus, the bit-wise output data BWOD may include a portion of the first temporary page data FRD-1, a portion of the second temporary page data FRD-2, and a portion of the third temporary page data FRD-3. Subsequently, the bit-wise output data BWOD may be output to the memory controller 200, and then may be stored in the first through third buffer memories 220-1, 220-2, and 220-3 of the memory controller 200 by categorizing the bit-wise output data BWOD by the first through third temporary page data FRD-1, FRD-2, and FRD-3. That is, when the bit-wise output data BWOD are stored in the first through third buffer memories 220-1, 220-2, and 220-3 of the memory controller 200, one bit P11 of the first temporary page data FRD-1 may be stored in the first buffer memory 220-1, one bit P12 of the second temporary page data FRD-2 may be stored in the second buffer memory 220-2, and one bit P13 of the third temporary page data FRD-3 may be stored in the third buffer memory 220-3. In this way, the first through third temporary page data FRD-1, FRD-2, and FRD-3 stored in the first through third page buffers 120-1, 120-2, and 120-3 of the NAND flash memory device 100 may be stored in the first through third buffer memories 220-1, 220-2, and 220-3 of the memory controller 200, respectively. Here, an error correction for the page data may be performed based on the first through third temporary page data FRD-1, FRD-2, and FRD-3 while the first through third temporary page data FRD-1, FRD-2, and FRD-3 are output to the memory controller 200. As a result, the method of FIG. 5 may enable a memory system including the NAND flash memory device 100 to operate at a high speed while achieving high reliability for the page data.

FIG. 8 is a diagram illustrating an example embodiment in which chunk-wise output data are output by the method of FIG. 5.

Referring to FIG. 8, the NAND flash memory device 100 may include first through third page buffers 120-1, 120-2, and 120-3, and the memory controller 200 may include first through third buffer memories 220-1, 220-2, and 220-3. Here, the chunk-wise output data CWOD may be output from the NAND flash memory device 100 to the memory controller 200 by the method of FIG. 5. Although it is illustrated in FIG. 8 that the first through third page buffers 120-1, 120-2, and 120-3 are arranged in a vertical direction with respect to the first through third page buffers 120-1, 120-2, and 120-3, and the first through third buffer memories 220-1, 220-2, and 220-3 are also arranged in a vertical direction with respect to the first through third buffer memories 220-1, 220-2, and 220-3, an actual arrangement of the first through third page buffers 120-1, 120-2, and 120-3 and an actual arrangement of the first through third buffer memories 220-1, 220-2, and 220-3 are not limited thereto. For convenience of description, it is assumed in FIG. 8 that an I/O size between the NAND flash memory device 100 and the memory controller 200 is six bits.

Specifically, when the first through third temporary page data FRD-1, FRD-2, and FRD-3 are generated by reading one page data based on first through third verification voltages from a memory cell array and respectively stored in the first through third page buffers 120-1, 120-2, and 120-3, the chunk-wise output data CWOD (i.e., the buffer output data) may be generated by selecting respective portions of the first through third temporary page data FRD-1, FRD-2, and FRD-3 by a unit of plural bits (i.e., chunk) in a vertical direction with respect to the first through third page buffers 120-1, 120-2, and 120-3. Here, a size of chunk may be determined according to requirements of a memory system. For example, the chunk-wise output data CWOD may be generated by selecting plural bits P11 and P11 of the first temporary page data FRD-1, plural bits P12 and P12 of the second temporary page data FRD-2, and plural bits P13 and P13 of the third temporary page data FRD-3. In this case, the chunk-wise output data CWOD may have six bits corresponding to the I/O size between the NAND flash memory device 100 and the memory controller 200. Thus, the chunk-wise output data CWOD may include a portion of the first temporary page data FRD-1, a portion of the second temporary page data FRD-2, and a portion of the third temporary page data FRD-3. Subsequently, the chunk-wise output data CWOD may be output to the memory controller 200, and then may be stored in the first through third buffer memories 220-1, 220-2, and 220-3 of the memory controller 200 by categorizing the chunk-wise output data CWOD by the first through third temporary page data FRD-1, FRD-2, and FRD-3. That is, when the chunk-wise output data CWOD are stored in the first through third buffer memories 220-1, 220-2, and 220-3 of the memory controller 200, plural bits P11 and P11 of the first temporary page data FRD-1 may be stored in the first buffer memory 220-1, plural bits P12 and P12 of the second temporary page data FRD-2 may be stored in the second buffer memory 220-2, and plural bits P13 and P13 of the third temporary page data FRD-3 may be stored in the third buffer memory 220-3. In this way, the first through third temporary page data FRD-1, FRD-2, and FRD-3 stored in the first through third page buffers 120-1, 120-2, and 120-3 of the NAND flash memory device 100 may be stored in the first through third buffer memories 220-1, 220-2, and 220-3 of the memory controller 200, respectively. Here, an error correction for the page data may be performed based on the first through third temporary page data FRD-1, FRD-2, and FRD-3 while the first through third temporary page data FRD-1, FRD-2, and FRD-3 are output to the memory controller 200. As a result, the method of FIG. 5 may enable a memory system including the NAND flash memory device 100 to operate at a high speed while achieving high reliability for the page data.

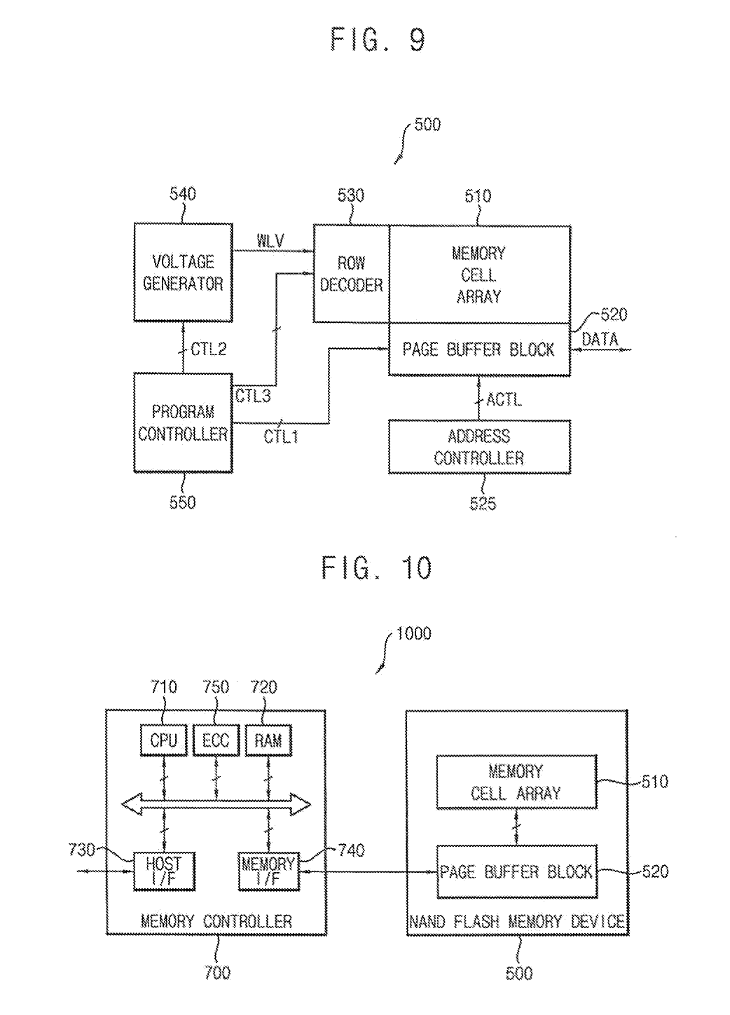

FIG. 9 is a block diagram illustrating a NAND flash memory device employing a method of reading page data according to example embodiments.

Referring to FIG. 9, the NAND flash memory device 500 may include a memory cell array 510, a page buffer block 520, an address controller 525, a row decoder 530, a voltage generator 540, and a program controller 550. In some example embodiments, the NAND flash memory device 500 may further include a pass-fail detector that verifies threshold voltage states of target multi-level cells when performing an increment step pulse program (ISPP) operation on the target multi-level cells.

The memory cell array 510 may include a plurality of multi-level cells. Here, the multi-level cells may be coupled to word-lines and bit-lines. The page buffer block 520 may include a plurality of page buffers. Here, the page buffer block 520 may operate as a write driver or a sense amplifier based on an operating mode of the NAND flash memory device 500. The address controller 525 may control an addressing operation of the page buffer block 520. Thus, the NAND flash memory device 500 may generate a portion group (i.e., referred to as buffer output data) by selecting a portion of every page data (or, every temporary page data) by a unit of one bit or by a unit of plural bits in a vertical direction with respect to the page buffers of the page buffer block 520, and may sequentially output the portion group to a memory controller when outputting a plurality of page data (or, temporary page data) read from the memory cell array 510 and stored in the page buffers of the page buffer block 520 to the memory controller. That is, the address controller 525 may control a portion of every page data to be selected by a unit of one bit or by a unit of plural bits in a vertical direction with respect to the page buffers of the page buffer block 520 by controlling an addressing operation of the page buffer block 520 based on an address control signal ACTL. The row decoder 530 may receive word-line voltages WLV such as a program voltage, a pass voltage, a verification voltage, a read voltage, etc from the voltage generator 540, and may apply the word-line voltages WLV to the word-lines of the memory cell array 510 based on a row address. The voltage generator 540 may generate the word-line voltages WLV to be applied to the word-lines of the memory cell array 510 based on an operating mode of the NAND flash memory device 500. The program controller 550 may control the page buffer block 520, the voltage generator 530, and the row decoder 540 by outputting control signals CTL1, CTL2, and CTL3 to the page buffer block 520, the voltage generator 530, and the row decoder 540. As described above, the NAND flash memory device 500 including the address controller 525 may sequentially output the buffer output data (i.e., bit-wise output data or chunk-wise output data) to the memory controller, where the buffer output data are generated by selecting a portion of every page data by a unit of one bit or by a unit of plural bits in a vertical direction with respect to the page buffers of the page buffer block 520. As a result, a memory system including the NAND flash memory device may efficiently read the page data, and may operate at a high speed while achieving high reliability for the page data. In example embodiments, the address controller 525 may be implemented as hardware and/or software components.

FIG. 10 is a block diagram illustrating a memory system including the NAND flash memory device of FIG. 9.

Referring to FIG. 10, the memory system 1000 may include a NAND flash memory device 500 and a memory controller 700. Since the NAND flash memory device 500 is described above, duplicated description will not be repeated. In example embodiments, the memory system 1000 may be implemented as an embedded multi-media card (EMMC), a secure digital (SD) card, a compact flash (CF) card, a memory stick, an XD picture card, etc.

The NAND flash memory device 500 may output buffer output data (i.e., bit-wise output data or chunk-wise output data) to the memory controller 700, where the buffer output data are generated by selecting a portion of every page data (or, every temporary page data) by a unit of one bit or by a unit of plural bits in a vertical direction with respect to a plurality of page buffers. The memory controller 700 may control an operation of the NAND flash memory device 500. In an example embodiment, the memory controller 700 may include a central processing unit 710, at least one buffer memory 720, a host interface 730, a memory interface 740, and an error correction circuit 750. Here, the error correction circuit 750 may perform an error correction for the page data based on the buffer output data by performing a hard decision and/or a soft decision. In this case, soft decision logic may be included in the error correction circuit 750. Thus, the memory controller 700 may perform an error correction for the page data based on hard decision data and its error correction code. In addition, the memory controller 700 may perform a further error correction for the page data based on additional information (i.e., soft decision data) related to reliability of the hard decision data. As a result, the memory system 1000 may operate at a high speed while achieving high reliability for the page data. In example embodiments, the host interface 730 may interact with a host device based on a standard protocol such as a universal serial bus (USB), a multi media card (MMC), a peripheral component interconnect (PCI), a PCI-Express, an advanced technology attachment (ATA), a serial advanced technology attachment (SATA), a parallel advanced technology attachment (PATA), a small computer system interface (SCSI), an enhanced small device interface (ESDI), a serial attached SCSI (SAS), an integrated drive electronics (IDE), etc. In example embodiments, the memory interface 740 may interact with the NAND flash memory device 500 based on a NAND interface protocol. Although the NAND flash memory device 500 and the memory controller 700 are described above, structures of the NAND flash memory device 500 and the memory controller 700 may be designed in various ways according to requirements of the memory system 1000.

The present inventive concept may be applied to an electronic device including a NAND flash memory device. Thus, the present inventive concept may be applied to a computer, a laptop, a digital camera, a cellular phone, a smart phone, a smart pad, a personal digital assistant (PDA), a portable multimedia player (PMP), an MP3 player, a navigation system, a video phone, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of reading page data of a NAND flash memory device, the method comprising:
storing a plurality of page data in a plurality of page buffers, respectively, the page data being read from a memory cell array of the NAND flash memory device;
generating buffer output data by selecting respective portions of the page data in a vertical direction with respect to the page buffers; and
outputting the buffer output data to a memory controller.

2. The method of claim 1, wherein the buffer output data is bit-wise output data that is generated by selecting the respective portions of the page data by a unit of one bit in the vertical direction with respect to the page buffers.

3. The method of claim 1, wherein the buffer output data is chunk-wise output data that is generated by selecting the respective portions of the page data by a unit of plural bits in the vertical direction with respect to the page buffers.

4. The method of claim 1, wherein the buffer output data is stored in at least one buffer memory of the memory controller by categorizing the buffer output data by the page data.

5. The method of claim 4, wherein a size of the buffer output data corresponds to an input/output (I/O) size between the NAND flash memory device and the memory controller.

6. A method of reading page data of a NAND flash memory device, the method comprising:
storing first through (N)th temporary page data, where N is an integer greater than or equal to 2, in first through (N)th page buffers, respectively, the first through (N)th temporary page data being generated by reading one page data from a memory cell array of the NAND flash memory device based on first through (N)th verification voltages;
generating buffer output data by selecting respective portions of the first through (N)th temporary page data in a vertical direction with respect to the first through (N)th page buffers; and
outputting the buffer output data to a memory controller.

7. The method of claim 6, wherein the buffer output data is bit-wise output data that is generated by selecting the respective portions of the first through (N)th temporary page data by a unit of one bit in the vertical direction with respect to the first through (N)th page buffers.

8. The method of claim 6, wherein the buffer output data is chunk-wise output data that is generated by selecting the respective portions of the first through (N)th temporary page data by a unit of plural bits in the vertical direction with respect to the first through (N)th page buffers.

9. The method of claim 6, wherein the buffer output data is stored in at least one buffer memory of the memory controller by categorizing the buffer output data by the first through (N)th temporary page data, and
wherein an error correction for the page data is performed based on the buffer output data provided to the buffer memory of the memory controller.

10. The method of claim 9, wherein a size of the buffer output data corresponds to an input/output (I/O) size between the NAND flash memory device and the memory controller.
